(19) United States
(12) Patent Application Publication
(10) Pub. No.: US 2024/0074249 A1
(43) Pub. Date: Feb. 29, 2024

(54) DISPLAY DEVICE AND METHOD FOR MANUFACTURING THE SAME

(71) Applicant: Samsung Display Co., LTD., Yongin-si (KR)

(72) Inventors: Yang-Ho JUNG, Yongin-si (KR); Woong Sik KIM, Yongin-si (KR); Kab Jong SEO, Yongin-si (KR); Jun Ho SIM, Yongin-si (KR); Jae Hun LEE, Yongin-si (KR)

(21) Appl. No.: 18/453,841

(22) Filed: Aug. 22, 2023

(30) Foreign Application Priority Data
Aug. 25, 2022 (KR) 10-2022-0106908

(51) Int. Cl. H10K 59/123; H10K 59/12; H10K 59/80; H10K 71/60

(52) U.S. Cl. CPC H10K 59/123; H10K 59/1201; H10K 59/877; H10K 71/60

(57) ABSTRACT

The present disclosure relates to a display device and a manufacturing method thereof, and a display device according to one or more embodiments includes a substrate, a transistor above the substrate, a first pixel electrode connected to the transistor, a scattering layer above the first pixel electrode, and defining repeating protrusions and depressions, a second pixel electrode above the scattering layer, and connected with the first pixel electrode, an emission layer above the second pixel electrode, and a common electrode above the emission layer.

### CROSS-REFERENCE TO RELATED APPLICATION

This application claims priority to, and the benefit of, Korean Patent Application No. 10-2022-0106908 filed in the Korean Intellectual Property Office on Aug. 25, 2022, the entire contents of which are incorporated herein by reference.

### BACKGROUND

### 1. Field

The present disclosure relates to a display device and a manufacturing method thereof.

### 2. Description of the Related Art

A display device is a device that displays a screen, and includes a liquid crystal display (LCD), an organic light-emitting diode (OLED) display, and the like. These display devices are used in various electronic devices, such as portable phones, navigation devices, digital cameras, electronic books, portable game devices, or various terminals.

The organic light-emitting diode display has self-luminance characteristics, and unlike the liquid crystal display, the organic light-emitting diode display does not require a separate light source, and thus the thickness and the weight can be reduced. In addition, organic light-emitting diode display has high quality characteristics, such as low power consumption, high luminance, and fast response speed.

The above information disclosed in this Background section is only for enhancement of understanding of the background of the described technology, and therefore may contain information that does not form the prior art that is already known in this country to a person of ordinary skill in the art.

### SUMMARY

Embodiments are to provide a display device that can improve a viewing angle and luminance, and a manufacturing method thereof.

A display device according to one or more embodiments includes a substrate, a transistor above the substrate, a first pixel electrode connected to the transistor, a scattering layer above the first pixel electrode, and defining repeating protrusions and depressions, a second pixel electrode above the scattering layer, and connected with the first pixel electrode, an emission layer above the second pixel electrode, and a common electrode above the emission layer.

The scattering layer may define grooves, wherein at least one of the second pixel electrode, the emission layer, and the common electrode defines protrusions and depressions.

A depth of the grooves may be less than or equal to a maximum thickness of the scattering layer.

The depth of the grooves may be half of the maximum thickness of the scattering layer.

The protrusions and the depressions may correspond to convex portions between the grooves or to the grooves.

An interval of the protrusions and the depressions may be constant.

A width of one of the protrusions or one of the depressions may be about 1.0 μm or more and about 10 μm or less, wherein an interval between centers of adjacent ones of the protrusions or adjacent ones of the depressions is greater than about 3 μm and less than about 30 μm.

The scattering layer may overlap an upper surface and side surfaces of the first pixel electrode, and defines an opening, wherein the second pixel electrode is connected to the first pixel electrode through the opening of the scattering layer.

The scattering layer may have a same flat shape as the first pixel electrode, wherein the second pixel electrode is in contact with a side of the first pixel electrode.

The scattering layer may include a photosensitive resin, and scatterers in the photosensitive resin.

A manufacturing method of a display device according to one or more embodiments includes forming a transistor above a substrate, forming a passivation layer above the transistor, forming a first pixel electrode above the passivation layer and connected with the transistor, forming a scattering layer above the first pixel electrode, and defining protrusions and depressions, forming a second pixel electrode above the scattering layer and connected with the first pixel electrode, forming an emission layer above the second pixel electrode, and forming a common electrode above the emission layer.

Forming the scattering layer may include patterning the scattering layer to have grooves, wherein at least one of the second pixel electrode, the emission layer, and the common electrode define protrusions and depressions.

Forming the scattering layer may include using a halftone mask or a slit mask, wherein a depth of the grooves is equal to or less than a maximum thickness of the scattering layer.

Forming the scattering layer may include using a general mask, wherein the depth of the grooves is equal to the maximum thickness of the scattering layer.

The protrusions and the depressions of the scattering layer may correspond to convex portions between the grooves or to the grooves.

An interval between the protrusions and the depressions may be constant.

A width of one of the protrusions or one of the depressions may be about 1.0 μm or more and about 10 μm or less, wherein an interval between centers of adjacent ones of the protrusions or adjacent ones of the depressions is greater than about 3 μm and less than about 30 μm.

Forming the scattering layer may include patterning the scattering layer to define openings, wherein the second pixel electrode is connected to the first pixel electrode through one of the openings of the scattering layer, and wherein the scattering layer overlaps an upper surface and side surfaces of the first pixel electrode.

The manufacturing method of the display device may further include, after patterning the scattering layer, patterning the first pixel electrode using the scattering layer as a mask, wherein the second pixel electrode is in contact with a side of the first pixel electrode.

Forming the scattering layer may include, applying a photosensitive resin material including scatterers, and performing a photo process.

According to the embodiments, a viewing angle and luminance of the display device can be improved.

### BRIEF DESCRIPTION OF THE DRAWINGS

FIG. 1 is a cross-sectional view of a display device according to one or more embodiments.

FIG. 2 to FIG. 13 are cross-sectional and plan views that sequentially show a manufacturing method of a display device according to one or more embodiments.

FIG. 14 is a cross-sectional view of a display device according to one or more embodiments.

FIG. 15 is a cross-sectional view of a display device according to one or more embodiments.

FIG. 16 to FIG. 24 are cross-sectional and plan views that sequentially show a manufacturing method of a display device according to one or more embodiments.

FIG. 25 is a cross-sectional view of a display device according to one or more embodiments.

FIG. 26 is a top plan view of a part of a display device according to one or more embodiments.

FIG. 27 is a cross-sectional view of a display device according to Comparative example 1.

FIG. 28 is a cross-sectional view of a display device according to Comparative example 2.

FIG. 29 is a cross-sectional view of the display device according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

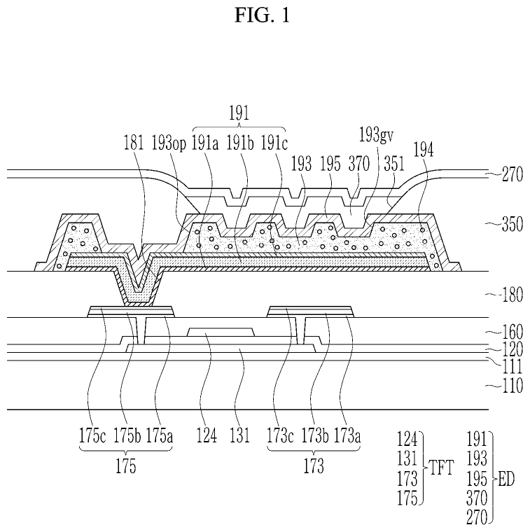

Hereinafter, referring to FIG. 1, a display device according to one or more embodiments will be described.

FIG. 1 is a cross-sectional view of a display device according to one or more embodiments.

As shown in FIG. 1, a display device according to one or more embodiments includes a substrate 110, a transistor TFT positioned on the substrate 110, and a light-emitting diode ED connected to the transistor TFT.

The substrate 110 may be a rigid substrate or a flexible substrate that can be bent, folded, or rolled. For example, the substrate 110 may include a material, such as polystyrene, polyvinyl alcohol, polymethylmethacrylate, polyethersulfone, polyacrylate, polyetherimide, polyethylene naphthalate, polyethylene terephthalate, polyphenylene sulfide, polyarylate, polyimide, polycarbonate, triacetate cellulose, cellulose acetate propionate, and the like. The substrate 110 may be single-layered or multi-layered. In the substrate 110, at least one base layer containing a polymer resin and at least one inorganic layer may be alternately laminated.

A buffer layer 111 for flattening a surface of the substrate 110 and blocking penetration of impurity elements may be further positioned on the substrate 110. The buffer layer 111 may include an inorganic insulating material, such as a silicon nitride (SiNₓ), a silicon oxide (SiOₓ), and a silicon oxynitride (SiOₓN_{y}), or an organic insulating material. The buffer layer 111 may be a single-layer or multi-layered structure of the material. A barrier layer may be further positioned on the substrate 110. In this case, the barrier layer may be positioned between the substrate 110 and the buffer layer 111. The barrier layer may include an inorganic insulating material, such as a silicon nitride (SiNₓ), a silicon oxide (SiOₓ), and/or a silicon oxynitride (SiOₓN_{y}). The barrier layer may be a single layer or multi-layered structure of the material.

A semiconductor 131 may be positioned on the buffer layer 111. The semiconductor 131 may include any one of amorphous silicon, polycrystalline silicon, and/or an oxide semiconductor. For example, the semiconductor 131 may include low temperature polysilicon (LTPS) or an oxide semiconductor material containing at least one of zinc (Zn), indium (In), gallium (Ga), tin (Sn), and/or a mixture thereof. For example, the semiconductor 131 may include an indium-gallium-zinc oxide (IGZO). The semiconductor 131 may include a channel region, a first region, and a second region classified according to impurity doping, respectively. The first region and the second region may be positioned on respective sides of the channel region of the semiconductor 131. The first region and the second region may have conductivity characteristics corresponding to conductors.

A gate-insulating layer 120 may be positioned on the semiconductor 131. The gate-insulating layer 120 may cover the semiconductor 131 and the buffer layer 111. The gate-insulating layer 120 may include an inorganic insulating material, such as a silicon nitride (SiNₓ), a silicon oxide (SiOₓ), and/or a silicon oxynitride (SiOₓN_{y}). The gate-insulating layer 120 may have a single-layer or multi-layered structure of the material.

A gate electrode 124 may be positioned on the gate-insulating layer 120. The gate electrode 124 may overlap at least a portion of the semiconductor 131. The gate electrode 124 may include a metal, such as copper (Cu), molybdenum (Mo), aluminum (Al), silver (Ag), chromium (Cr), tantalum (Ta), or titanium (Ti), or a metal alloy thereof. The gate electrode 124 may be formed of a single layer or multiple layers. For example, the gate electrode 124 may be formed of a double layer, and may include a layer including aluminum (Al) and a layer including titanium (Ti).

After forming the gate electrode 124, a doping process or plasma treatment may be performed. A portion of the semiconductor 131 covered by the gate electrode 124 is not doped or plasma treated, and a portion of the semiconductor 131 not covered by the gate electrode 124 is doped or plasma treated to have the same characteristics as the conductor. A region overlapping the gate electrode 124 on a plane of the semiconductor 131 may be the channel region.

An interlayer insulating layer 160 may be positioned on the gate electrode 124. The interlayer insulating layer 160 may cover the gate electrode 124 and the gate-insulating layer 120. The interlayer insulating layer 160 may include an inorganic insulating material, such as a silicon nitride (SiNₓ), a silicon oxide (SiOₓ), and a silicon oxynitride (SiOₓN_{y}). The interlayer insulating layer 160 may have a single-layer or multi-layered structure of the material.

A source electrode 173 and a drain electrode 175 may be positioned on the interlayer insulating layer 160. The source electrode 173 and the drain electrode 175 are respectively connected to the first region and the second region of the semiconductor 131 via openings formed in the interlayer insulating layer 160 and the gate-insulating layer 120. Accordingly, the aforementioned semiconductor 131, the gate electrode 124, the source electrode 173, and the drain electrode 175 form one transistor TFT. Depending on embodiments, the transistor TFT may include only the first region and second region of the semiconductor 131 instead of the source electrode 173 and the drain electrode 175. In FIG. 1, one transistor TFT is illustrated, but the display device according to one or more embodiments may include a plurality of pixels, and each of the plurality of pixels may include a plurality of transistors TFT.

The source electrode 173 and drain electrode 175 may include a metal, such as aluminum (Al), copper (Cu), silver (Ag), gold (Au), platinum (Pt), palladium (Pd), nickel (Ni), molybdenum (Mo), tungsten (W), titanium (Ti), chromium (Cr), or tantalum (Ta), or a metal alloy thereof. The source electrode 173 and the drain electrode 175 may be formed of a single layer or multiple layers. For example, the source electrode 173 may be formed of a triple layer including a lower layer 173a, a middle layer 173b, and an upper layer 173c. In this case, the lower layer 173a and the upper layer 173c of the source electrode 173 may include titanium (Ti), and the middle layer 173b may include aluminum (Al). The drain electrode 175 may be formed of a triple layer including a lower layer 175a, a middle layer 175b, and an upper layer 175c. In this case, the lower layer 175a and the upper layer 175c of the drain electrode 175 may include titanium (Ti), and the middle layer 175b may include aluminum (Al).

A passivation layer 180 may be positioned on the source electrode 173 and the drain electrode 175. The passivation layer 180 covers the source electrode 173, the drain electrode 175, and the interlayer insulating layer 160. The passivation layer 180 is for planarizing the surface of the substrate 110 equipped with the transistor TFTs, and may be an organic insulator. The passivation layer 180 may include an organic insulating material, such as general-purpose polymers, such as poly(methyl methacrylate) (PMMA) or polystyrene (PS), polymer derivatives with phenolic groups, acryl-based polymers, imide-based polymers, polyimides, and siloxane-based polymers.

A light-emitting diode ED may be positioned on the passivation layer 180. The light-emitting diode ED may be connected to the transistor TFT. The light-emitting diode ED may include a first pixel electrode 191, a second pixel electrode 195, an emission layer 370, and a common electrode 270. The light-emitting diode ED may further include a scattering layer 193 positioned between the first pixel electrode 191 and the second pixel electrode 195.

The first pixel electrode 191 may be positioned on the passivation layer 180. The first pixel electrode 191 may be formed of a single layer including a transparent conductive oxide or metal material or a multi-layer including the same. The transparent conductive oxide may include an indium tin oxide (ITO), poly-ITO, an indium zinc oxide (IZO), an indium gallium zinc oxide (IGZO), and/or an indium tin zinc oxide (ITZO). The metal material may include silver (Ag), molybdenum (Mo), copper (Cu), gold (Au), and/or aluminum (Al). For example, the first pixel electrode 191 may include a lower layer 191a, a middle layer 191b, and an upper layer 191c. The lower layer 191a of the first pixel electrode 191 may be positioned on the passivation layer 180, the middle layer 191b may be positioned on the lower layer 191a, and the upper layer 191c may be positioned on the middle layer 191b. In this case, the middle layer 191b of the first pixel electrode 191 may be formed of a different material from that of the lower layer 191a and the upper layer 191c. For example, the middle layer 191b may be formed of silver (Ag), and the lower layer 191a and the upper layer 191c may be formed of ITO.

The passivation layer 180 may include an opening 181 overlapping the first pixel electrode 191 and the drain electrode 175. The first pixel electrode 191 may be connected to the drain electrode 175 through the opening 181. Accordingly, the first pixel electrode 191 may be connected to the transistor TFT. In this case, the lower layer 191a of the first pixel electrode 191 and the upper layer 175c of the drain electrode 175 may contact each other.

A scattering layer 193 may be positioned on the first pixel electrode 191. The scattering layer 193 may be positioned directly above the upper layer 191c of the first pixel electrode 191 and may contact the upper layer 191c of the first pixel electrode 191. The scattering layer 193 may cover the top and side surfaces of the first pixel electrode 191. The scattering layer 193 may be positioned directly above the first pixel electrode 191, and may come into contact with the first pixel electrode 191. The scattering layer 193 may contact the upper surface of the upper layer 191c of the first pixel electrode 191, and may contact side surfaces of the lower layer 191a, the middle layer 191b, and the upper layer 191c. The scattering layer 193 may have a width that is wider than the first pixel electrode 191. An edge of the scattering layer 193 may be positioned directly above the passivation layer 180. The scattering layer 193 may include/define an opening 193op, and the first pixel electrode 191 is not covered by the scattering layer 193 at a portion where the opening 193op is formed. The opening 193op of the scattering layer 193 may overlap the opening 181 of the passivation layer 180. The scattering layer 193 may include a photosensitive resin and a scatterer 194. The photosensitive resin may include a positive-type photosensitive resin or a negative-type photosensitive resin. A plurality of scatterers 194 may be positioned inside the photosensitive resin, and may be evenly distributed. The scatterer 194 may include materials, such as TiO₂, SiO₂, BaSO₄, ZnO, Al₂O₃, and/or CaCO₃. The display device according to one or more embodiments may change a light path via a scattering layer 193 including the scatterer 194. A viewing angle may be improved by scattering light incident to the scattering layer 193.

The scattering layer 193 may include/define a groove 193gv. Accordingly, the scattering layer 193 may have a shape including protrusions and depressions including a convex portion and a recess portion on a cross-section. The scattering layer 193 may include a plurality of grooves 193gv, and each groove 193gv may have a constant width. An interval between the plurality of grooves 193gv may be constant. The planar shape of the groove 193gv may be, for example, circular or polygonal. The groove 193gv may have a width that is gradually increased as it moves away from the substrate 110 on the cross-section. However, it is not limited thereto, and the groove 193gv may have a constant width on the cross-section, and may have a gradually narrowing width as the distance from the substrate 110 increases. The groove 193gv may have a depth (e.g., predetermined depth). For example, the depth of the groove 193gv may be about half of the maximum thickness of the scattering layer 193.

A second pixel electrode 195 may be positioned on the scattering layer 193. The second pixel electrode 195 may cover the top and side surfaces of the scattering layer 193. The second pixel electrode 195 may be positioned directly above the scattering layer 193, and may come into contact with the scattering layer 193. The second pixel electrode 195 may have protrusions and depressions similar to the shape of the scattering layer 193 according to the shape of the scattering layer 193. The second pixel electrode 195 may be formed to cover the bottom and side surfaces of the groove 193gv of the scattering layer 193. The scattering layer 193 and the second pixel electrode 195 may serve as a lens that can improve light-condensing efficiency. Therefore, the efficiency of the light emitted from the front can be increased, and the luminance can be improved. The second pixel electrode 195 may also be formed within an opening 193op of the scattering layer 193. The second pixel electrode 195 may be positioned directly above the first pixel electrode 191 within the opening 193op, and may come into contact with the first pixel electrode 191. Accordingly, the second pixel electrode 195 may be connected to the first pixel electrode 191 through the opening 193op. The second pixel electrode 195 may have a wider width than the first pixel electrode 191 and the scattering layer 193. An edge of the second pixel electrode 195 may be positioned directly above the passivation layer 180. The second pixel electrode 195 may include a transparent conductive oxide, such as an indium tin oxide (ITO), a poly-ITO, an indium zinc oxide (IZO), an indium gallium zinc oxide (IGZO), and/or an indium tin zinc oxide (ITZO).

A partitioning wall 350 may be positioned on the second pixel electrode 195. The partitioning wall 350 is also referred to as a pixel defining layer (PDL), and includes/defines a pixel opening 351 overlapping at least a part of the second pixel electrode 195. The pixel opening 351 may also overlap the first pixel electrode 191 and the scattering layer 193. In this case, the pixel opening 351 may overlap the center of the first pixel electrode 191, the scattering layer 193, and the second pixel electrode 195, but might not overlap the edge of the first pixel electrode 191, the scattering layer 193, and the second pixel electrode 195. Accordingly, a size of the pixel opening 351 on the plane may be smaller than a size of the first pixel electrode 191, the scattering layer 193, and the second pixel electrode 195 on a plane. The partitioning wall 350 may be an organic insulator containing at least one material selected from a group consisting of polyimide, polyamide, acryl resin, benzocyclobutene, and/or phenol resin. Alternatively, the partitioning wall 350 may include an inorganic insulating material, such as a silicon nitride (SiNₓ), a silicon oxide (SiOₓ), and/or a silicon oxynitride (SiOₓN_{y}). Alternatively, the partitioning wall 350 may be formed of a black pixel-defining layer (BPDL) including a light-blocking material. In this case, the light-blocking material may include carbon black, carbon nanotubes, a resin containing a black dye or paste, metal particles, for example, of nickel, aluminum, molybdenum, and alloys thereof, metal oxide particles (e.g., chromium oxide) or metal nitride particles (e.g., chromium nitride), and the like. When the partitioning wall 350 includes a light-blocking material, reflection of external light by metal structures located under the partitioning wall 350 may be reduced. However, it is not limited thereto, and the partitioning wall 350 may include a light-transmitting organic insulating material instead of a light-blocking material.

An emission layer 370 may be positioned within the pixel opening 351 of the partitioning wall 350. The emission layer 370 may overlap the first pixel electrode 191, the scattering layer 193, and the second pixel electrode 195. In the pixel opening 351, the emission layer 370 may be positioned directly above the second pixel electrode 195. The emission layer 370 may have protrusion and depression shapes similar to the shapes of the second pixel electrode 195 and the scattering layer 193. The emission layer 370 may include an organic material for emitting red, green, and blue light. The emission layer 370 may include a low-molecular or high-molecular organic material. Although the emission layer 370 is shown as a single layer, an auxiliary layer, such as a hole injection layer (HIL), a hole transporting layer (HTL), an electron transporting layer (ETL), and an electron injection layer (EIL) may be substantially further formed above and below the emission layer 370. In this case, the hole injection layer and hole transport layer may be positioned below the emission layer 370, and the electron transport layer and the electron injection layer may be positioned above the emission layer 370.

A common electrode 270 may be positioned on the emission layer 370 and the partitioning wall 350. The common electrode 270 may be entirely positioned over most regions on the substrate 110. The common electrode 270 may be positioned directly above the emission layer 370. A portion of the common electrode 270 overlapping the emission layer 370 may have a shape including protrusions and depressions that is similar to the shapes of the emission layer 370, the second pixel electrode 195, and the scattering layer 193. The common electrode 270 is also called a cathode, and may include a reflective metal including calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), calcium (Ca), and/or the like, or may include a transparent conductive oxide (TCO), such as an indium tin oxide (ITO) or an indium zinc oxide (IZO).

The first pixel electrode 191, the second pixel electrode 195, the emission layer 370, and the common electrode 270 together may form the light-emitting diode ED. In this case, the first pixel electrode 191 and the second pixel electrode 195 may be an anode that is a hole injection electrode, and the common electrode 270 may be a cathode that is an electron injection electrode. However, it is not limited to this, and the anode and cathode may be formed in the opposite direction according to the driving method of the display device.

Holes and electrons are respectively injected into the emission layer 370 from the first and second pixel electrodes 191 and 195 and the common electrode 270, and light emission occurs when excitons that are combination of the injected holes and electrons fall from an excited state to a ground state.

In one or more embodiments, an encapsulation layer may be further positioned on the common electrode 270. The encapsulation layer is for protecting the light-emitting diode ED from moisture or oxygen that may inflow from the outside, and may include at least one inorganic layer and at least one organic layer. For example, the encapsulation layer may have a shape in which a first inorganic encapsulation layer, an organic encapsulation layer, and a second inorganic encapsulation layer are stacked. However, this is only an example, and the number of inorganic films and organic films constituting the encapsulation layer may be variously changed.

The display device according to one or more embodiments may include the plurality of pixels, and each pixel may include the plurality of transistors and the light-emitting diode connected to them. Although the structure of one transistor connected to the light-emitting diode has been described above, the plurality of transistors may be positioned within one pixel. For example, one pixel may include two transistors and a light-emitting diode connected to them. Some of the plurality of transistors included in one pixel may be formed of polycrystalline transistors, and other parts may be formed of oxide transistors.

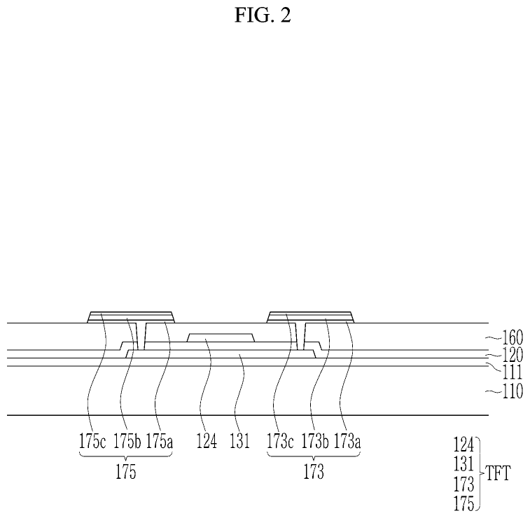

Hereinafter, referring to FIG. 2 to FIG. 13, a manufacturing method of a display device according to one or more embodiments will be described.

FIG. 2 to FIG. 13 are cross-sectional and plan views that sequentially show a manufacturing method of a display device according to one or more embodiments.

As shown in FIG. 2, a buffer layer 111 is formed using an inorganic insulating material, such as a silicon nitride (SiNₓ), a silicon oxide (SiOₓ), and a silicon oxynitride (SiOₓN_{y}), or an organic insulating material on a substrate 110. The buffer layer 111 may be entirely formed on the substrate 110.

A semiconductor 131 is formed on the buffer layer 111 using a semiconductor material, such as amorphous silicon, polycrystalline silicon, and/or an oxide semiconductor material. A gate-insulating layer 120 is formed using an inorganic insulating material, such as a silicon nitride (SiNₓ), a silicon oxide (SiOₓ), and/or a silicon oxynitride (SiOₓN_{y}) on the semiconductor 131.

A gate electrode 124 is formed using a metal, such as copper (Cu), molybdenum (Mo), aluminum (Al), silver (Ag), chromium (Cr), tantalum (Ta), titanium (Ti), or a metal alloy thereof on the gate-insulating layer 120. In this case, the gate electrode 124 may be formed by continuously depositing two or more metal material layers and then concurrently or substantially simultaneously patterning them. Subsequently, a doping process or plasma treatment may be performed. A portion of the semiconductor 131 covered by the gate electrode 124 may be a channel without being subjected to doping or plasma treatment. A portion of the semiconductor 131 not covered by the gate electrode 124 may be doped or plasma-treated to have the same characteristics as the conductor, and may be a first region and a second region. The first region and the second region of the semiconductor 131 may be positioned on both sides of the channel. An interlayer insulating layer 160 is formed using an inorganic insulating material, such as a silicon nitride (SiNₓ), a silicon oxide (SiOₓ), and a silicon oxynitride (SiOₓN_{y}) on the gate electrode 124. An opening is formed by patterning the interlayer insulating layer 160 and the gate-insulating layer 120 using a photo and etching process.

A source electrode 173 and a drain electrode 175 are formed using a metal, such as aluminum (Al), copper (Cu), silver (Ag), gold (Au), platinum (Pt), palladium (Pd), nickel (Ni), molybdenum (Mo), tungsten (W), titanium (Ti), chromium (Cr), or tantalum (Ta), or a metal alloy thereof, on the interlayer insulating layer 160

In this case, after continuously depositing and forming two or more metal material layers, the source electrode 173 and the drain electrode 175 may be formed by concurrently or substantially simultaneously patterning them. For example, after sequentially forming a material layer including titanium, a material layer including aluminum, and a material layer including titanium, the source electrode 173 and the drain electrode 175 may be formed by patterning these material layers. In this case, the source electrode 173 may be formed of a triple layer including a lower layer 173a, a middle layer 173b, and an upper layer 173c. In addition, the drain electrode 175 may be formed of a triple layer including a lower layer 175a, a middle layer 175b, and an upper layer 175c.

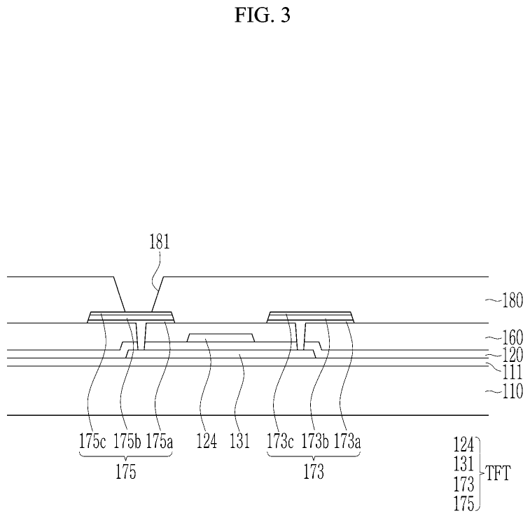

As shown in FIG. 3, a passivation layer 180 is formed using an organic insulating material, such as general-purpose polymers, such as poly(methyl methacrylate) (PMMA) or polystyrene (PS), polymer derivatives with phenolic groups, acryl-based polymers, imide-based polymers, a polyimide, and/or siloxane-based polymers on the source electrode 173 and the drain electrode 175. An opening 181 is formed by patterning the passivation layer 180. An upper surface of the drain electrode 175 may be exposed to the outside by the opening 181. In this case, the upper layer 175c of the drain electrode 175 is exposed by the opening 181.

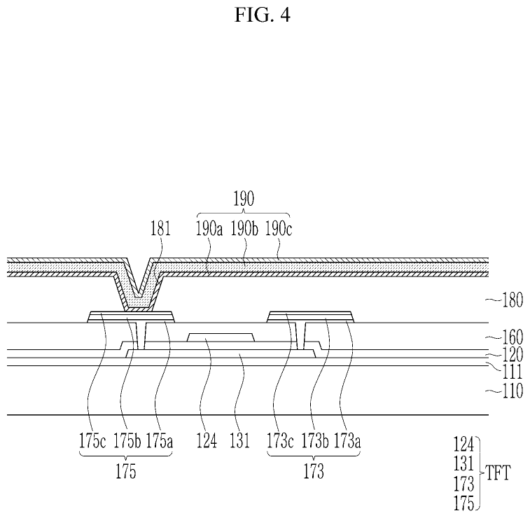

As shown in FIG. 4, a pixel electrode material layer 190 is on the passivation layer 180 using a transparent conductive oxide or a metal material. The pixel electrode material layer 190 may include a lower layer 190a, a middle layer 190b, and an upper layer 190c. The lower layer 190a, the middle layer 190b, and the upper layer 190c may be sequentially formed by continuous deposition. The middle layer 190b may be positioned directly above the lower layer 190a, and the upper layer 190c may be positioned directly above the middle layer 190b. In this case, the middle layer 190b of the pixel electrode material layer 190 may be formed of a different material from that of the lower layer 190a and the upper layer 190c. The middle layer 190b of the pixel electrode material layer 190 may be formed of a metal material, and the lower layer 190a and the upper layer 190c may be formed of a transparent conductive oxide. For example, the lower layer 190a may be formed using ITO, the middle layer 190b may be formed using silver (Ag), and the upper layer 190c may be formed using ITO. The pixel electrode material layer 190 may be connected to the drain electrode 175 through the opening 181. In this case, the lower layer 190a of the pixel electrode material layer 190 may contact the drain electrode 175.

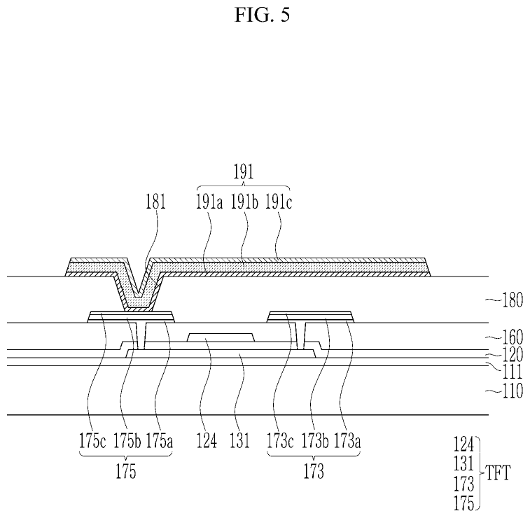

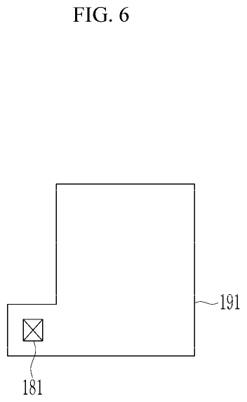

As shown in FIG. 5 and FIG. 6, the pixel electrode material layer 190 is patterned to form the first pixel electrode 191. In this case, the pixel electrode material layer 190 may be patterned using a wet etching process. When the pixel electrode material layer 190 including the lower layer 190a, the middle layer 190b, and the upper layer 190c is patterned, the first pixel electrode 191 including the lower layer 191a, the middle layer 191b, and the upper layer 191c may be formed. The lower layer 191a of the first pixel electrode 191 may be positioned on the passivation layer 180, the middle layer 191b may be positioned on the lower layer 191a, and the upper layer 191c may be positioned on the middle layer 191b. In this case, the middle layer 191b of the first pixel electrode 191 may be formed of a material that is different from that of the lower layer 191a and the upper layer 191c. The middle layer 191b of the first pixel electrode 191 may be formed of a metal material, and the lower layer 191a and the upper layer 191c may be formed of a transparent conductive oxide. For example, the middle layer 191b may be formed of silver (Ag), and the lower layer 191a and the upper layer 191c may be formed of ITO. The first pixel electrode 191 may be connected to the drain electrode 175 through the opening 181. In this case, the lower layer 191a of the first pixel electrode 191 and the upper layer 175c of the drain electrode 175 may contact each other. The planar shape of the first pixel electrode 191 may be approximately polygonal. However, it is not limited thereto, and the planar shape of the first pixel electrode 191 may be variously changed to a circular shape.

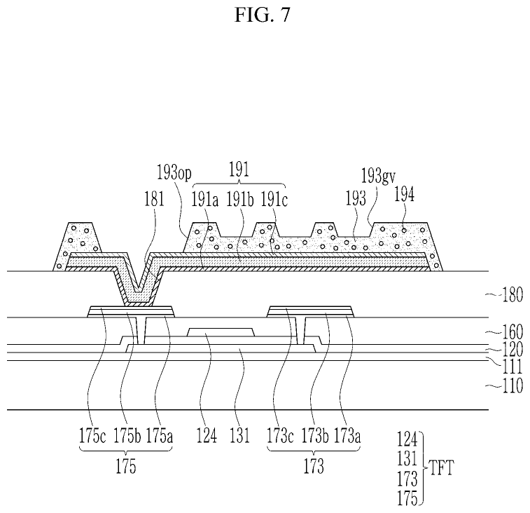

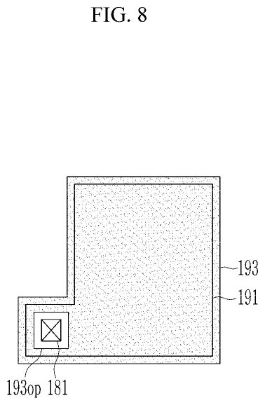

As shown in FIG. 7 and FIG. 8, a photosensitive resin material including a scatterer 194 is applied on the first pixel electrode 191 and patterned using a photo process to form a scattering layer 193. The photosensitive resin may include a positive-type photosensitive resin or a negative-type photosensitive resin. In this case, patterning may be performed using a halftone mask or a slit mask, and the scattering layer 193 may have different thicknesses according to respective positions.

Accordingly, the scattering layer 193 may have a shape including protrusions and depressions including a convex portion and a recess portion on a cross-section. The scattering layer 193 may include/define a groove 193gv and an opening 193op. The groove 193gv and the opening 193op may have different depths. For example, the depth of the groove 193gv may be about half of the maximum thickness of the scattering layer 193, and may correspond to the maximum thickness of the deep scattering layer 193 of the opening 193op. The scattering layer 193 may include a plurality of grooves 193gv, and each groove 193gv may have a constant width. An interval between the plurality of grooves 193gv may be constant. The planar shape of the groove 193gv may be, for example, circular or polygonal. The groove 193gv may have a width that is gradually increased as it moves away from the substrate 110 on the cross-section. However, it is not limited thereto, and the groove 193gv may have a constant width on the cross-section, and may have a width that is gradually decreased as the distance from the substrate 110 increases. In a portion where the opening 193op is formed, the first pixel electrode 191 is not covered by the scattering layer 193. The opening 193op of the scattering layer 193 may overlap the opening 181 of the passivation layer 180.

A plurality of scatterers 194 may be positioned inside the photosensitive resin material and may be evenly distributed. The scatterer 194 may include materials, such as TiO₂, SiO₂, BaSO₄, ZnO, Al₂O₃, and/or CaCO₃. The scattering layer 193 may be positioned directly above the upper layer 191c of the first pixel electrode 191, and may contact the upper layer 191c of the first pixel electrode 191. The scattering layer 193 may cover the top and side surfaces of the first pixel electrode 191. The scattering layer 193 may be positioned directly above the first pixel electrode 191, and may come into contact with the first pixel electrode 191. The scattering layer 193 may contact an upper surface of the upper layer 191c of the first pixel electrode 191, and may contact side surfaces of the lower layer 191a, the middle layer 191b, and the upper layer 191c. The scattering layer 193 may contact the upper surface of the pixel electrode material layer 190. In the process of forming the scattering layer 193, the side surface of the first pixel electrode 191 may not be exposed to the outside. In the process of forming the scattering layer 193, the middle layer 191b and the lower layer 191a of the first pixel electrode 191 may not be exposed to the outside. In the manufacturing method of the display device according to one or more embodiments, it is possible to reduce or prevent the likelihood of the side surface of the first pixel electrode 191 being damaged by the developer supplied in the process of forming the scattering layer 193.

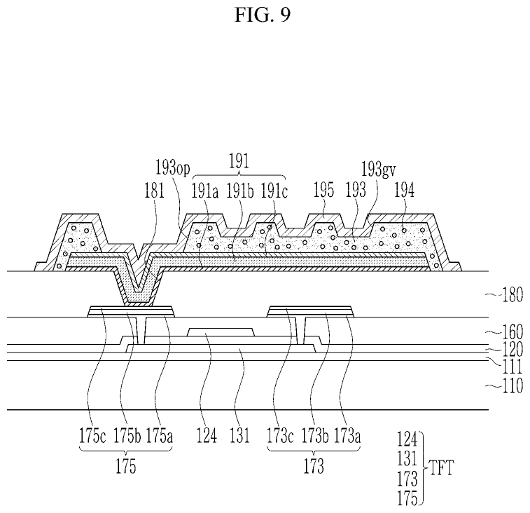

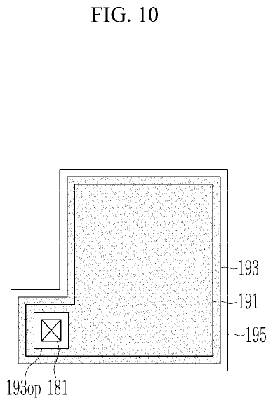

As shown in FIG. 9 and FIG. 10, a second pixel electrode 195 is formed on the scattering layer 193 using a transparent conductive oxide including an indium tin oxide (ITO), poly-ITO, an indium zinc oxide (IZO), an indium gallium zinc oxide (IGZO), and an indium tin zinc oxide (ITZO). The second pixel electrode 195 may cover the upper and side surfaces of the scattering layer 193. The second pixel electrode 195 may be positioned directly above the scattering layer 193 and may come into contact with the scattering layer 193. The second pixel electrode 195 may have protrusions and depressions similar to/according to the shape of the scattering layer 193. The second pixel electrode 195 may be formed to cover the bottom and side surfaces of the groove 193gv of the scattering layer 193. The scattering layer 193 and the second pixel electrode 195 may serve as a lens that can improve light-condensing efficiency. Therefore, the efficiency of the light emitted from the front can be increased and the luminance can be improved. The second pixel electrode 195 may also be formed within an opening 193op of the scattering layer 193. The second pixel electrode 195 may be positioned directly above the first pixel electrode 191 within the opening 193op, and may come into contact with the first pixel electrode 191. Accordingly, the second pixel electrode 195 may be connected to the first pixel electrode 191 through the opening 193op. The second pixel electrode 195 may have a width that is wider than the first pixel electrode 191 and the scattering layer 193. An edge of the second pixel electrode 195 may be positioned directly above the passivation layer 180.

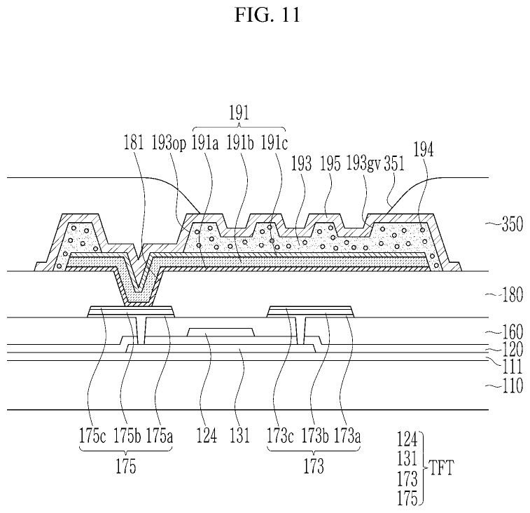

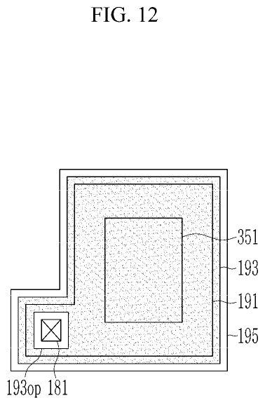

As shown in FIG. 11 and FIG. 12, a partitioning wall 350 is formed on the second pixel electrode 195 and the passivation layer 180 using an organic insulating material or an inorganic insulating material. The pixel opening 351 may be formed by patterning the partitioning wall 350. The pixel opening 351 may overlap the first pixel electrode 191, the scattering layer 193, and the second pixel electrode 195. In this case, the pixel opening 351 may overlap centers of the first pixel electrode 191, the scattering layer 193, and the second pixel electrode 195, but might not overlap edges of the first pixel electrode 191, the scattering layer 193, and the second pixel electrode 195.

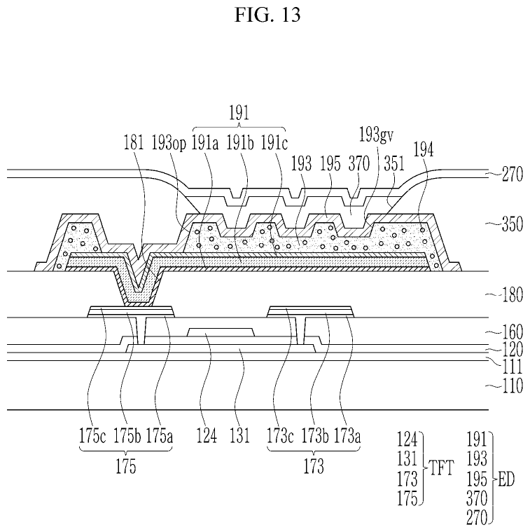

As shown in FIG. 13, an emission layer 370 may be formed within the pixel opening 351. The emission layer 370 may overlap the first pixel electrode 191, the scattering layer 193, and the second pixel electrode 195. Within the pixel opening 351, the emission layer 370 may be positioned directly above the second pixel electrode 195. The emission layer 370 may have protrusion and depression shapes that are similar to the shapes of the second pixel electrode 195 and the scattering layer 193. In FIG. 13, the emission layer 370 is illustrated as a single layer, but an auxiliary layer, such as an electron injection layer (EIL), a hole injection layer (HIL), a hole transporting layer (HTL), and an electron transporting layer (ETL) may be further formed above and below the emission layer 370.

Next, a common electrode 270 is formed using a reflective metal including calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), calcium (Ca), and the like, or may include a transparent conductive oxide (TCO), such as an indium tin oxide (ITO) or an indium zinc oxide (IZO) on the emission layer 370 and the partitioning wall 350. The common electrode 270 may be entirely positioned over most regions on the substrate 110. The common electrode 270 may be positioned directly above the emission layer 370. A portion of the common electrode 270 overlapping the emission layer 370 may have a protrusions and depressions shape that are similar to the shapes of the emission layer 370, the second pixel electrode 195, and the scattering layer 193. The first pixel electrode 191, the second pixel electrode 195, the emission layer 370, and the common electrode 270 together may form the light-emitting diode ED.

In one or more embodiments, an encapsulation layer may be formed on the common electrode 270.

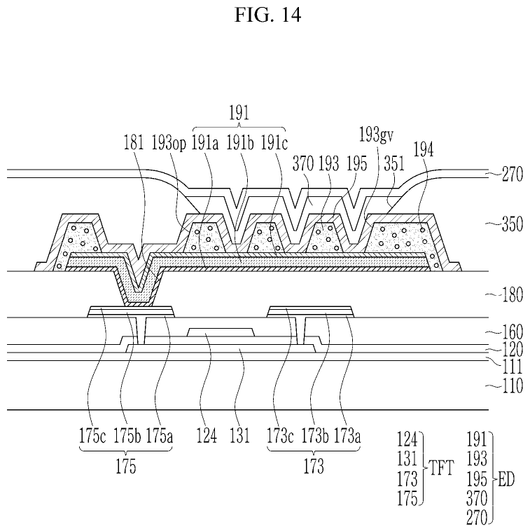

Next, referring to FIG. 14, a display device according to one or more embodiments will be described.

A display device according to one or more embodiments shown in FIG. 14 is almost the same as the display device according to the one or more embodiments corresponding to FIG. 1, and therefore a repeated description of the same parts is omitted. The presently described one or more embodiments differs from those described above in that a depth of a groove of a scattering layer corresponds to a depth of an opening, which will be further described below.

FIG. 14 is a cross-sectional view of a display device according to one or more embodiments.

As shown in FIG. 14, a display device according to one or more embodiments includes a substrate 110, a transistor TFT positioned on the substrate 110, and a light-emitting diode ED connected with the transistor TFT.

The light-emitting diode ED may include a first pixel electrode 191, a second pixel electrode 195, an emission layer 370, and a common electrode 270. The light-emitting diode ED may further include a scattering layer 193 positioned between the first pixel electrode 191 and the second pixel electrode 195.

The scattering layer 193 may include/define a groove 193gv and an opening 193op. In the previously described one or more embodiments, the depth of the groove 193gv and the depth of the opening 193op may be different, and in the presently described one or more embodiments, a depth of the groove 193gv may correspond to a depth of the opening 193op. Accordingly, the first pixel electrode 191 might not be covered by the scattering layer 193 in a portion where the groove 193gv is formed.

In the previously described one or more embodiments, a halftone mask, a slit mask, and the like may be used to form thicknesses of the scattering layer 193 differently according to the position, and in the presently described one or more embodiments, the scattering layer 193 having a constant thickness can be formed using a general mask. Compared to the previously described one or more embodiments, in the presently described one or more embodiments, a difference in height between a convex portion of the scattering layer 193 and a recess portion may be greater.

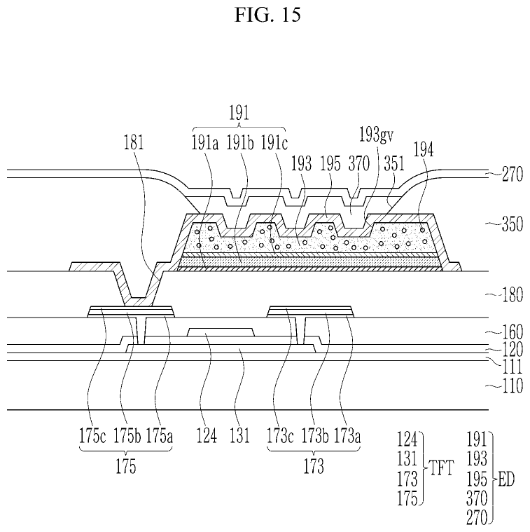

Next, a display device according to one or more embodiments will be described with reference to FIG. 15.

A display device according to one or more embodiments shown in FIG. 15 is almost the same as the display device according to the one or more embodiments corresponding to FIG. 1, and therefore a repeated description of the same parts is omitted. The presently described one or more embodiments differs from those described above in that a scattering layer and a first pixel electrode have similar widths, which will be further described below.

FIG. 15 is a cross-sectional view of a display device according to one or more embodiments.

As shown in FIG. 15, a display device according to one or more embodiments includes a substrate 110, a transistor TFT positioned on the substrate 110, and a light-emitting diode ED connected with the transistor TFT.

The light-emitting diode ED may include a first pixel electrode 191, a second pixel electrode 195, an emission layer 370, and a common electrode 270. The light-emitting diode ED may further include a scattering layer 193 positioned between the first pixel electrode 191 and the second pixel electrode 195.

The scattering layer 193 may include/define a groove 193gv and an opening 193op. In the previously described one or more embodiments, the first pixel electrode 191 may be directly connected to the drain electrode 175, and in the presently described one or more embodiments, the first pixel electrode 191 may not be directly connected to a drain electrode 175. The first pixel electrode 191 may not be positioned within an opening 181 of the passivation layer 180.

A scattering layer 193 may be positioned on the first pixel electrode 191. In the previously described one or more embodiments, the scattering layer 193 may cover the upper surface and the side surface of the first pixel electrode 191, and in the presently described one or more embodiments, the scattering layer 193 may cover a top surface of the first pixel electrode 191 and may not cover side surfaces. The scattering layer 193 may contact the upper surface of the upper layer 191c of the first pixel electrode 191, and might not contact the lower layer 191a and the middle layer 191b. The scattering layer 193 might not contact side surfaces of the lower layer 191a, the middle layer 191b, and the upper layer 191c of the first pixel electrode 191. The scattering layer 193 may have a width that is similar to that of the first pixel electrode 191. The width of the scattering layer 193 may be substantially the same as that of the first pixel electrode 191.

The scattering layer 193 may include/define a groove 193gv. The scattering layer 193 may include a plurality of grooves 193gv, and each groove 193gv may have a constant width. The groove 193gv may have a depth (e.g., predetermined depth). For example, the depth of the groove 193gv may be about half of the maximum thickness of the scattering layer 193.

A second pixel electrode 195 may be positioned on the scattering layer 193. The second pixel electrode 195 may cover an upper surface and side surfaces of the scattering layer 193. The second pixel electrode 195 may be positioned directly above the scattering layer 193, and may come into contact with the scattering layer 193. The second pixel electrode 195 may have protrusions and depressions similar to the shape of the scattering layer 193 according to the shape of the scattering layer 193. The second pixel electrode 195 may be formed to cover the bottom and side surfaces of the groove 193gv of the scattering layer 193. The scattering layer 193 and the second pixel electrode 195 may serve as a lens that can improve light-condensing efficiency. Therefore, the efficiency of the light that is emitted from the front can be increased, and the luminance can be improved. In addition, the second pixel electrode 195 may cover the side of the first pixel electrode 191. The second pixel electrode 195 may contact the side of the first pixel electrode 191 and may be connected to the first pixel electrode 191. The second pixel electrode 195 may also be formed within the opening 181 of the passivation layer 180. The second pixel electrode 195 may be connected to the drain electrode 175 through the opening 181. Accordingly, the second pixel electrode 195 may be connected to the transistor TFT. In this case, the second pixel electrode 195 may come into contact with the upper layer 175c of the drain electrode 175. The first pixel electrode 191 may not be directly connected to the drain electrode 175, but may be connected to the drain electrode 175 through the second pixel electrode 195.

A partitioning wall 350 may be positioned on the second pixel electrode 195. The partitioning wall 350 may include/define a pixel opening 351, and the pixel opening 351 may overlap the first pixel electrode 191, the scattering layer 193, and the second pixel electrode 195. An emission layer 370 may be positioned within the pixel opening 351 of the partitioning wall 350. The emission layer 370 may have protrusion and depression shapes similar to the shapes of the second pixel electrode 195 and the scattering layer 193. A common electrode 270 may be positioned on the emission layer 370 and the partitioning wall 350. A portion of the common electrode 270 overlapping the emission layer 370 may have a protrusions and depressions shape similar to the shape of the emission layer 370, the second pixel electrode 195, and the scattering layer 193.

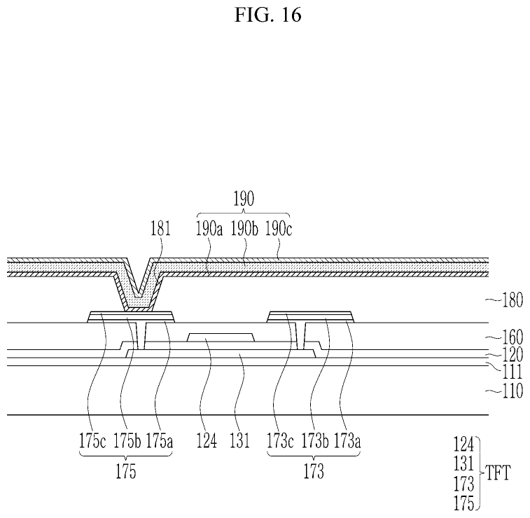

Next, referring to FIG. 16 to FIG. 24, a manufacturing method of a display device according to one or more embodiments will be described.

FIG. 16 to FIG. 24 are cross-sectional and plan views that sequentially show a manufacturing method of a display device according to one or more embodiments.

First, as shown in FIG. 16, a buffer layer 111 is formed on a substrate 110, and a transistor TFT including a semiconductor 131, a gate electrode 124, a source electrode 173, and a drain electrode 175 is formed on the buffer layer 111. A passivation layer 180 is formed on the source electrode 173 and the drain electrode 175, and an opening 181 is formed by patterning the passivation layer 180.

Next, a pixel electrode material layer 190 is formed on the passivation layer 180 using a transparent conductive oxide or a metal material. The pixel electrode material layer 190 may include a lower layer 190a, a middle layer 190b, and an upper layer 190c. The lower layer 190a, the middle layer 190b, and the upper layer 190c may be sequentially formed by continuous deposition.

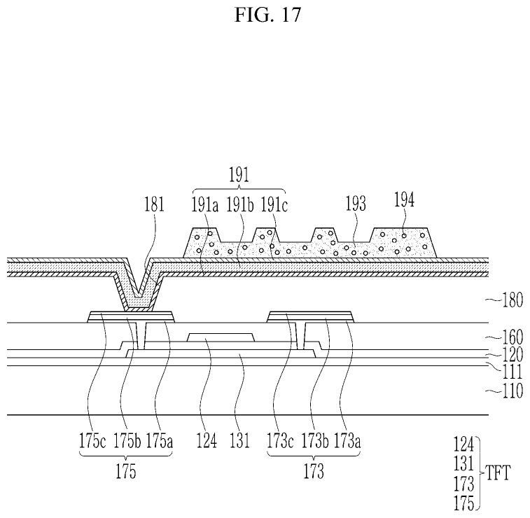

As shown in FIG. 17, a photosensitive resin material including a scatterer 194 is applied on the pixel electrode material layer 190 and patterned using a photo process to form a scattering layer 193. In the photo process, an exposure process can be performed using a halftone mask or a slit mask. The photosensitive resin may include a positive-type photosensitive resin or a negative-type photosensitive resin. In this case, patterning may be performed using a halftone mask or a slit mask, and the scattering layer 193 may have different thicknesses according to positions. Accordingly, the scattering layer 193 may include a plurality of grooves 193gv, and may have a shape including protrusions and depressions including a convex portion and a recess portion on a cross-section. The scattering layer 193 might not overlap an opening 181 of the passivation layer 180.

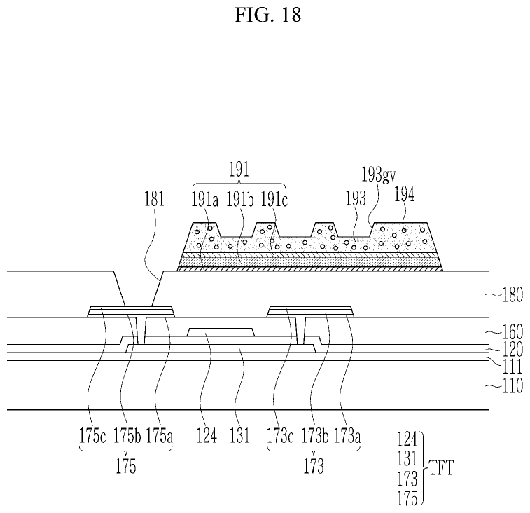

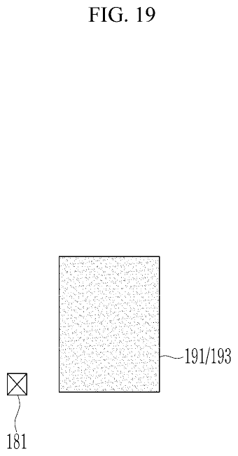

As shown in FIG. 18 and FIG. 19, the first pixel electrode 191 is formed by patterning the pixel electrode material layer 190 using the scattering layer 193 as a mask. The first pixel electrode 191 may include a lower layer 191a, a middle layer 191b, and an upper layer 191c. The first pixel electrode 191 may have substantially the same planar shape as the scattering layer 193. The first pixel electrode 191 may have substantially the same width as the scattering layer 193. The scattering layer 193 may cover an upper surface of the first pixel electrode 191. A side surface of the first pixel electrode 191 is not covered by the scattering layer 193, and may be exposed to the outside. In the manufacturing method of the display device according to one or more embodiments, the first pixel electrode 191 and the scattering layer 193 are concurrently or substantially simultaneously formed using one mask, thereby simplifying the manufacturing process and reducing cost and time. In addition, because the side surface of the first pixel electrode 191 is not exposed to a developing solution during the formation of the scattering layer 193, damage to the side surface of the first pixel electrode 191 can be reduced or prevented.

The first pixel electrode 191 might not overlap the opening 181 of the passivation layer 180. Therefore, the first pixel electrode 191 may not be formed within the opening 181, and may not be directly connected to the drain electrode 175.

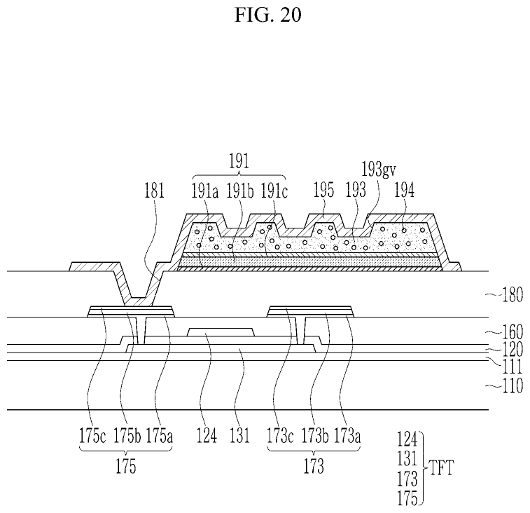

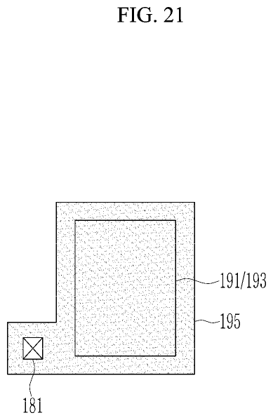

As shown in FIG. 20 and FIG. 21, a second pixel electrode 195 is formed on the scattering layer 193 and the passivation layer 180. The second pixel electrode 195 may cover an upper surface and side surfaces of the scattering layer 193. The second pixel electrode 195 may have protrusions and depressions similar to the shape of the scattering layer 193 according to the shape of the scattering layer 193. The second pixel electrode 195 may be formed to cover the bottom and side surfaces of the groove 193gv of the scattering layer 193. The scattering layer 193 and the second pixel electrode 195 serve as a lens that can improve light-condensing efficiency. Therefore, the efficiency of the light emitted from the front can be increased and the luminance can be improved. The second pixel electrode 195 may have a wider width than that of the scattering layer 193 and the first pixel electrode 191. The second pixel electrode 195 may cover the side of the first pixel electrode 191 and may contact the side of the first pixel electrode 191. The second pixel electrode 195 may also be formed in the opening 181, and may be connected to the drain electrode 175 through the opening 181. The first pixel electrode 191 may be connected to the drain electrode 175 through the second pixel electrode 195.

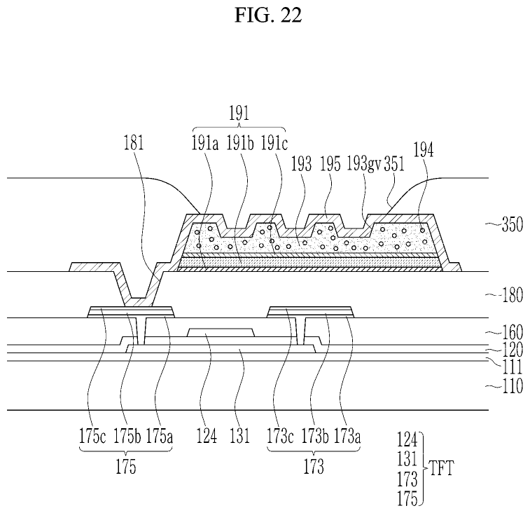

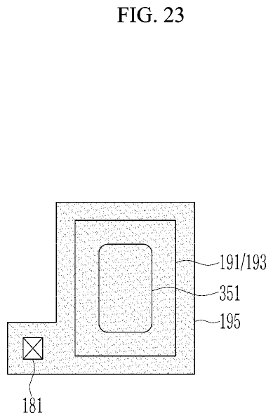

As shown in FIG. 22 and FIG. 23, a partitioning wall 350 is formed on the second pixel electrode 195 and the passivation layer 180, and a pixel opening 351 is formed by patterning the partitioning wall 350. In this case, the pixel opening 351 may overlap centers of the first pixel electrode 191, the scattering layer 193, and the second pixel electrode 195.

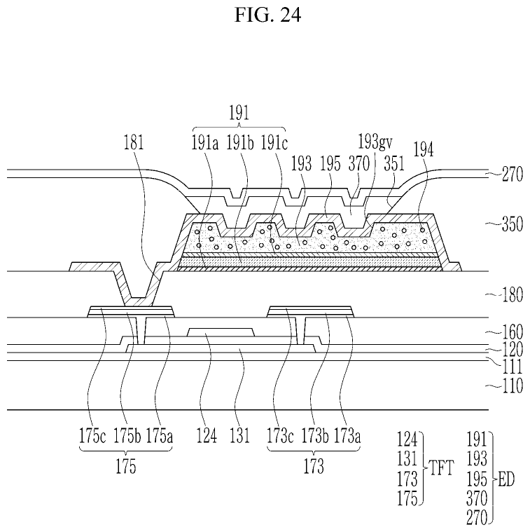

As shown in FIG. 24, an emission layer 370 is formed within the pixel opening 351. The emission layer 370 may have protrusion and depression shapes that are similar to the shapes of the second pixel electrode 195 and the scattering layer 193. Subsequently, a common electrode 270 is formed on the emission layer 370 and the partitioning wall 350. A portion of the common electrode 270 overlapping the emission layer 370 may have a protrusions and depressions having a shape that is similar to the shape of the emission layer 370, the second pixel electrode 195, and the scattering layer 193.

In one or more embodiments, an encapsulation layer may be formed on the common electrode 270.

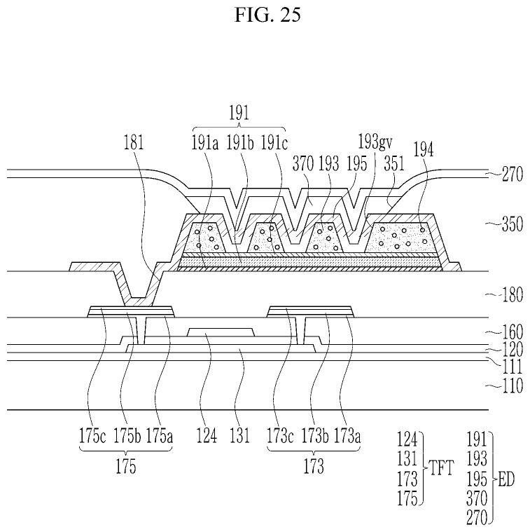

Next, referring to FIG. 25, the display device according to one or more embodiments will be described.

A display device according to one or more embodiments shown in FIG. 25 is almost the same as the display device according to the one or more embodiments corresponding to FIG. 15, and therefore a repeated description of the same parts is omitted. The presently described one or more embodiments differs from those described above in that a depth of a groove of a scattering layer corresponds to the maximum thickness of the scattering layer, which will be further described below.

FIG. 25 is a cross-sectional view of a display device according to one or more embodiments.

As shown in FIG. 25, a display device according to one or more embodiments includes a substrate 110, a transistor TFT positioned on the substrate 110, and a light-emitting diode ED connected with the transistor TFT.

The light-emitting diode ED may include a first pixel electrode 191, a second pixel electrode 195, an emission layer 370, and a common electrode 270. The light-emitting diode ED may further include a scattering layer 193 positioned between the first pixel electrode 191 and the second pixel electrode 195.

The scattering layer 193 may include/define a groove 193gv. In the previously described one or more embodiments, a depth of the groove 193gv may be less than the maximum thickness of the scattering layer 193, and in the presently described one or more embodiments, the depth of groove 193gv may correspond to the maximum thickness of the scattering layer 193. In the previously described one or more embodiments, the depth of the groove 193gv may be about half of the maximum thickness of the scattering layer 193. In the presently described one or more embodiments, the depth of the groove 193gv may be substantially equal to the maximum thickness of the scattering layer 193. Accordingly, the first pixel electrode 191 might not be covered by the scattering layer 193 in a portion where the groove 193gv is formed.

In the previously described one or more embodiments, a halftone mask, a slit mask, and the like may be used to form thicknesses of the scattering layer 193 differently according to respective positions, and in the presently described one or more embodiments, the scattering layer 193 having a constant thickness can be formed using a general mask. Compared to the previously described one or more embodiments, in the presently described one or more embodiments, a difference in height between a convex portion of the scattering layer 193 and a recess portion may be greater.

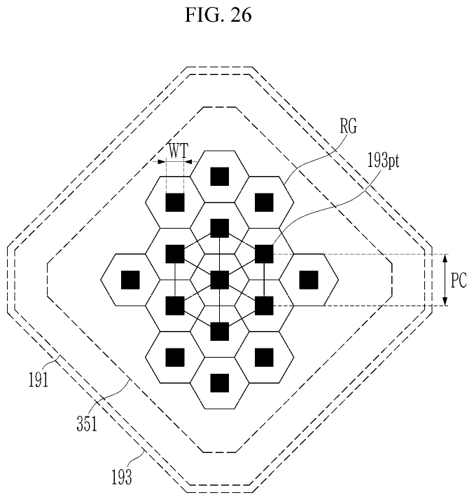

In the display device according to one or more embodiments, the thickness of the scattering layer is formed differently according to the position so as to serve as a lens. Hereinafter, a planar shape of a scattering layer of a display device according to one or more embodiments will be described with reference to FIG. 26.

FIG. 26 is a top plan view of a part of a display device according to one or more embodiments. FIG. 26 illustrates patterns of a first pixel electrode, a pixel opening, and a scattering layer.

As shown in FIG. 26, a display device according to one or more embodiments may include a first pixel electrode 191 and a scattering layer 193 overlapping each other. The pixel opening 351 may overlap centers of the first pixel electrode 191 and the scattering layer 193. The first pixel electrode 191, the scattering layer 193, and the pixel opening 351 may have similar planar shapes, and may have different respective sizes. The first pixel electrode 191, the scattering layer 193, and the pixel opening 351 may be formed in a polygonal or circular shape on a plane. For example, the first pixel electrode 191, the scattering layer 193, and the pixel opening 351 may be formed in a substantially quadrangular shape on a plane, and a corner portion may be chamfered. The first pixel electrode 191 may have the same size as the scattering layer 193 on a plane or may have a smaller size. The pixel opening 351 may have a smaller size than the first pixel electrode 191 on a plane.

The scattering layer 193 may include a repeated pattern 193pt. As described above, the scattering layer 193 may have a shape including protrusions and depressions including a convex portion and a recess portion, and the pattern 193pt of the scattering layer 193 may correspond to the convex portion. That is, the pattern 193pt of the scattering layer 193 may mean a relatively thick portion positioned between the grooves 193gv. However, it is not limited thereto, and on the contrary, the pattern 193pt of the scattering layer 193 may correspond to the recess portion. That is, the pattern 193pt of the scattering layer 193 may mean the groove 193gv. When the scattering layer 193 is formed using the same mask, its shape may vary depending on whether the material for forming the scattering layer includes a positive photosensitive resin or a negative photosensitive resin.

The scattering layer 193 may include a plurality of pattern forming regions RG, and one pattern 193pt may be located in each region RG. Each region RG may be formed as a regular hexagon, and a honeycomb shape may be formed by positioning the plurality of regions RG to contact each other. The pattern of 193pt may be located at a center of each region RG. A width WT of the pattern 193pt may be about 1.0 μm or more and about 10 μm or less. An interval PC between pattern 193pt may be constant. The interval PC between the pattern 193pt may be about 3 μm or more and about 30 μm or less. The number of patterns 193pt formed on the scattering layer 193 in one pixel may be about 1 or more and about 20 or less. However, it is not limited thereto, and the dispose shape, width, interval, number, and the like of the pattern of the scattering layer 193 may be variously changed in consideration of the resolution of the display device.

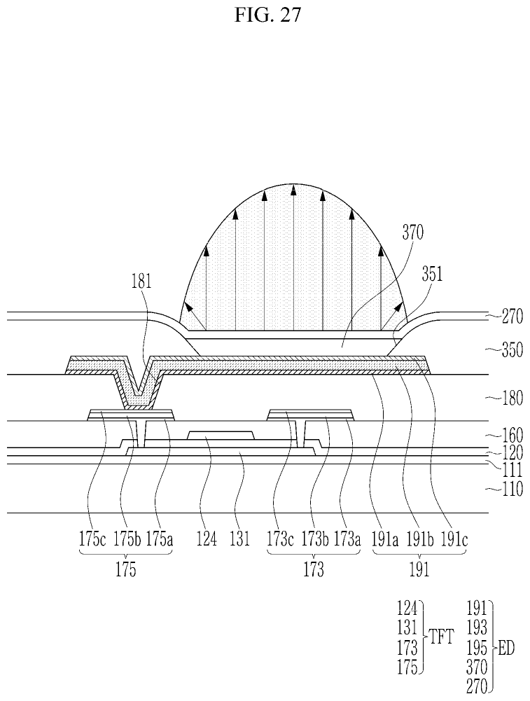

Hereinafter, referring to FIG. 27 to FIG. 29, the display device according to one or more embodiments and a display device according to a Comparative Example will be compared.

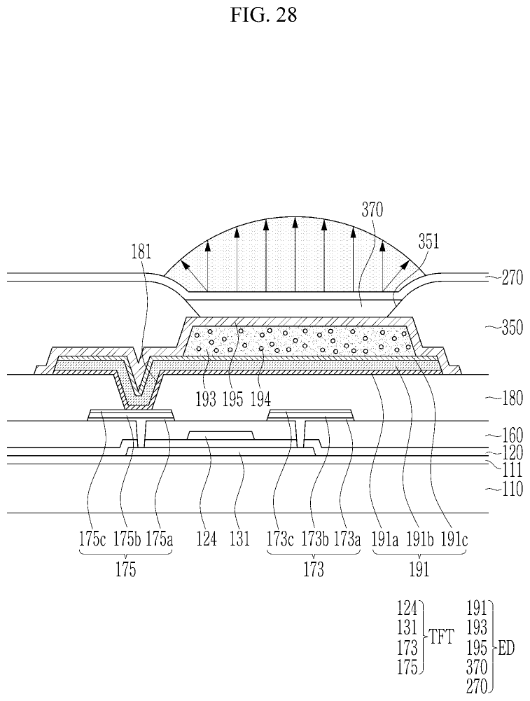

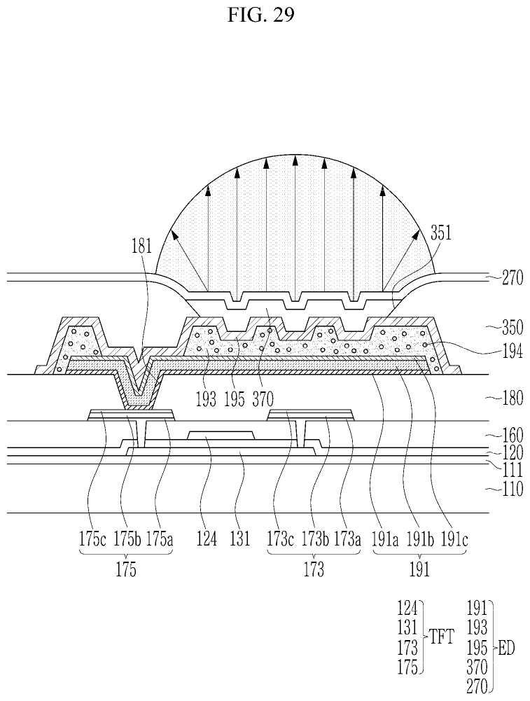

FIG. 27 is a cross-sectional view of a display device according to Comparative Example 1, FIG. 28 is a cross-sectional view of a display device according to Comparative Example 2, and FIG. 29 is a cross-sectional view of the display device according to one or more embodiments. In FIG. 27 to FIG. 29, an emission layer and a common electrode are omitted, and a path and an amount of light emitted from the light-emitting element are indicated by arrows.

As shown in FIG. 27, a display device according to Comparative Example 1 may include a first pixel electrode 191, and might not include a scattering layer and a second pixel electrode. In this case, in the light emitted from the light-emitting element, the amount of light emitted from the center of the pixel opening 351 may be a maximum, and the amount of light may decrease toward an edge of the pixel opening 351.

As shown in FIG. 28, a display device according to the Comparative Example 2 may include a first pixel electrode 191, a scattering layer 193, and a second pixel electrode 195, and an upper surface of the scattering layer 193 may be flat. That is, the scattering layer 193 might not include/define a groove. In this case, an optical path of the light emitted from the light-emitting diode may be changed by the scattering layer 193. Therefore, a light emission rate at an edge of the pixel opening 351 may be further increased, and a difference in light quantity between the center and the edge of the pixel opening 351 can be reduced. However, in the display device according to Comparative Example 2, the amount of light emitted from the center of the pixel opening 351 may be reduced compared to the display device according to Comparative Example 1.

As shown in FIG. 29, a display device according to one or more embodiments may include a first pixel electrode 191, a scattering layer 193, and a second pixel electrode 195, and the scattering layer 193 may include/define a groove 193gv and may have a shape including protrusions and depressions. The shape of the protrusions and depressions of the scattering layer 193 may serve as a lens that can increase light-condensing efficiency, and thus the light output rate at the center of the pixel opening 351 can be further increased. The display device according to one or more embodiments includes a scattering layer having a shape including protrusions and depressions, thereby increasing the amount of light at both the center and edge of the pixel opening 351 to improve the overall luminance.

While this disclosure has been described in connection with what is presently considered to be practical embodiments, it is to be understood that the present disclosure is not limited to the disclosed embodiments. On the contrary, it is intended to cover various modifications and equivalent arrangements included within the spirit and scope of the appended claims, with functional equivalents thereof to be included therein.

Description of Some of the Reference Characters

| | |
|---|---|
| 110: substrate | 191: first pixel electrode |
| 193: scattering layer | 194: scatterer |
| 195: second pixel electrode | 270: common electrode |
| 350: partitioning wall | 351: pixel opening |
| 370: emission layer | |

What is claimed is:

1. A display device comprising:
a substrate;
a transistor above the substrate;
a first pixel electrode connected to the transistor;
a scattering layer above the first pixel electrode, and defining repeating protrusions and depressions;
a second pixel electrode above the scattering layer, and connected with the first pixel electrode;
an emission layer above the second pixel electrode; and
a common electrode above the emission layer.

2. The display device of claim 1, wherein the scattering layer defines grooves, and
wherein at least one of the second pixel electrode, the emission layer, and the common electrode defines protrusions and depressions.

3. The display device of claim 2, wherein a depth of the grooves is less than or equal to a maximum thickness of the scattering layer.

4. The display device of claim 3, wherein the depth of the grooves is half of the maximum thickness of the scattering layer.

5. The display device of claim 2, wherein the protrusions and the depressions correspond to convex portions between the grooves or to the grooves.

6. The display device of claim 5, wherein an interval of the protrusions and the depressions is constant.

7. The display device of claim 6, wherein a width of one of the protrusions or one of the depressions is about 1.0 μm or more and about 10 μm or less, and
wherein an interval between centers of adjacent ones of the protrusions or adjacent ones of the depressions is greater than about 3 μm and less than about 30 μm.

8. The display device of claim 2, wherein the scattering layer overlaps an upper surface and side surfaces of the first pixel electrode, and defines an opening, and
wherein the second pixel electrode is connected to the first pixel electrode through the opening of the scattering layer.

9. The display device of claim 2, wherein the scattering layer has a same flat shape as the first pixel electrode, and
wherein the second pixel electrode is in contact with a side of the first pixel electrode.

10. The display device of claim 1, wherein the scattering layer comprises:
a photosensitive resin; and
scatterers in the photosensitive resin.

11. A manufacturing method of a display device, the method comprising:
forming a transistor above a substrate;
forming a passivation layer above the transistor;
forming a first pixel electrode above the passivation layer and connected with the transistor;
forming a scattering layer above the first pixel electrode, and defining protrusions and depressions;
forming a second pixel electrode above the scattering layer and connected with the first pixel electrode;
forming an emission layer above the second pixel electrode; and
forming a common electrode above the emission layer.

12. The manufacturing method of the display device of claim 11, wherein forming the scattering layer comprises patterning the scattering layer to have grooves,
wherein at least one of the second pixel electrode, the emission layer, and the common electrode define protrusions and depressions.

13. The manufacturing method of the display device of claim 12, wherein forming the scattering layer comprises using a halftone mask or a slit mask,
wherein a depth of the grooves is equal to or less than a maximum thickness of the scattering layer.

14. The manufacturing method of the display device of claim 13, wherein forming of the scattering layer comprises using a general mask,
wherein the depth of the grooves is equal to the maximum thickness of the scattering layer.

15. The manufacturing method of the display device of claim 12, wherein the protrusions and the depressions of the scattering layer correspond to convex portions between the grooves or to the grooves.

16. The manufacturing method of the display device of claim 15, wherein an interval between the protrusions and the depressions is constant.

17. The manufacturing method of the display device of claim 16, wherein a width of one of the protrusions or one of the depressions is about 1.0 μm or more and about 10 μm or less, and
wherein an interval between centers of adjacent ones of the protrusions or adjacent ones of the depressions is greater than about 3 μm and less than about 30 μm.

18. The manufacturing method of the display device of claim 12, wherein forming the scattering layer comprises patterning the scattering layer to define openings,
wherein the second pixel electrode is connected to the first pixel electrode through one of the openings of the scattering layer; and
wherein the scattering layer overlaps an upper surface and side surfaces of the first pixel electrode.

19. The manufacturing method of the display device of claim 12, further comprising, after patterning the scattering layer, patterning the first pixel electrode using the scattering layer as a mask,
wherein the second pixel electrode is in contact with a side of the first pixel electrode.

20. The manufacturing method of the display device of claim 11, wherein forming the scattering layer comprises, applying a photosensitive resin material comprising scatterers, and performing a photo process.
